(19) United States
(12) Patent Application Publication
(10) Pub. No.: US 2026/0173739 A1
(43) Pub. Date: Jun. 18, 2026

(54) DISPLAY APPARATUS, METHOD OF MANUFACTURING DISPLAY APPARATUS, AND ELECTRONIC APPARATUS

(71) Applicant: Samsung Display Co., Ltd., Yongin-si, Gyeonggi-do (KR)

(72) Inventor: Jaehoon Kim, Yongin-si (KR)

(73) Assignee: Samsung Display Co., Ltd., Yongin-si, Gyeonggi-do (KR)

(21) Appl. No.: 19/265,956

(22) Filed: Jul. 10, 2025

(30) Foreign Application Priority Data
Dec. 13, 2024 (KR) 10-2024-0186220

(51) Int. Cl. H10K 59/80; H10K 59/12; H10K 59/122; H10K 59/88

(52) U.S. Cl. CPC H10K 59/879; H10K 59/1201; H10K 59/122; H10K 59/873; H10K 59/88

(57) ABSTRACT

Provided is a display apparatus including a substrate including a display area and a peripheral area outside the display area, a plurality of display elements disposed on the display area, an encapsulation layer disposed on the plurality of display elements, a bank layer disposed on the encapsulation layer, and including an opening overlapping the plurality of display elements, the opening extending in a direction, a lens disposed on the encapsulation layer and overlapping the opening, and a height control pattern layer disposed on the peripheral area and disposed between the lens and the encapsulation layer.

### CROSS-REFERENCE TO RELATED APPLICATION(S)

This application claims priority to and the benefits of Korean Patent Application No. 10-2024-0186220, under 35 U.S.C. § 119, filed on December 13, 2024, in the Korean Intellectual Property Office, the entire contents of which are incorporated herein by reference.

### BACKGROUND

### 1. Technical Field

One or more embodiments relate to a display apparatus, a method of manufacturing the display apparatus, and an electronic apparatus, and more particularly, to a display apparatus including a lens, a method of manufacturing the display apparatus, and an electronic apparatus.

### 2. Description of the Related Art

To support various functions, an electronic apparatus includes a display apparatus that provides a user with visual information such as images. Display apparatuses operate by forming display elements such as an organic light-emitting diode, and a thin-film transistor on a substrate, and allowing the display elements to emit light. Specifically, the display element may include an emission layer between a pixel electrode and an opposite electrode. To adjust a path of light emitted from the emission layer of the display element, a lens is disposed on the display element. The lens is formed by discharging a lens-forming material on the display element through an inkjet printing process.

### SUMMARY

In a display apparatus according to the related art, the height of a lens is reduced toward the end portion of the lens and display quality of the display apparatus may deteriorate.

One or more embodiments include a display apparatus with improved display quality because a lens has a uniform height, a method of manufacturing the display apparatus, and an electronic apparatus. However, such a technical objective is just an example, and embodiments are not limited thereto.

Additional aspects will be set forth in part in the description which follows and, in part, will be apparent from the description, or may be learned by practice of the embodiments.

According to one or more embodiments, a display apparatus includes a substrate including a display area and a peripheral area outside the display area, a plurality of display elements disposed on the display area, an encapsulation layer disposed on the plurality of display elements, a bank layer disposed on the encapsulation layer, and including an opening overlapping the plurality of display elements, the opening extending in a direction, a lens disposed on the encapsulation layer and overlapping the opening, and a height control pattern layer disposed on the peripheral area and disposed between the lens and the encapsulation layer.

The lens may extend from the display area to the peripheral area.

The lens may extend from a portion of the peripheral area disposed adjacent to a side of the display area through the display area to a portion of the peripheral area disposed adjacent to an opposite side to the side.

In a plan view, the bank layer may surround the lens.

The bank layer may be disposed on the display area and the peripheral area, and a portion of the bank layer disposed on the peripheral area may be disposed on the height control pattern layer.

An end portion of the lens may be disposed on the height control pattern layer.

A thickness of the height control pattern layer may be reduced as being closer to the display area.

The height control pattern layer may include a first pattern layer disposed adjacent to a side of the display area, and a second pattern layer disposed adjacent to an opposite side to the side with the display area.

A portion of the lens may overlap a portion of the first pattern layer, and another portion of the lens may overlap a portion of the second pattern layer.

The encapsulation layer may include a first inorganic encapsulation layer, a second inorganic encapsulation layer, and an organic encapsulation layer disposed between the first inorganic encapsulation layer and the second inorganic encapsulation layer.

According to one or more embodiments, a method of manufacturing a display apparatus includes providing a substrate including a display area on which a plurality of display elements are disposed, and a peripheral area outside the display area, forming an encapsulation layer on the substrate to cover the plurality of display elements, forming a height control pattern layer on the peripheral area, forming, on the encapsulation layer, a bank layer including an opening overlapping the plurality of display elements, the opening extending in a direction, and forming, on the encapsulation layer, a lens overlapping the opening of the bank layer.

The forming of the lens may include coating a lens-forming material on the encapsulation layer to fill the opening, and irradiating an ultraviolet ray to the lens-forming material.

The forming of the lens may include coating the lens-forming material over the display area and the peripheral area.

The forming of the bank layer may include forming the bank layer such that the opening may extend from a portion of the peripheral area disposed adjacent to a side of the display area through the display area to a portion of the peripheral area disposed adjacent to an opposite side to the side.

The forming of the bank layer may include forming the bank layer on the display area and the peripheral area, and forming the bank layer such that a portion of the bank layer formed on the peripheral area may be formed on the height control pattern layer.

The forming of the lens may include coating the lens-forming material on a portion of the height control pattern layer.

The forming of the height control pattern layer may include forming the height control pattern layer such that a thickness of the height control pattern layer may be reduced as being closer to the display area.

The forming of the height control pattern layer may include forming a first pattern layer on a portion of the peripheral area disposed adjacent to a side of the display area, and forming a second pattern layer on another portion of the peripheral area disposed adjacent to an opposite side to the side.

The forming of the lens may include coating the lens-forming material on a portion of the first pattern layer and a portion of the second pattern layer.

According to one or more embodiments, an electronic apparatus includes a display apparatus, and a housing accommodating the display apparatus and forming an exterior of the electronic apparatus, wherein the display apparatus includes a substrate including a display area and a peripheral area outside the display area, a plurality of display elements disposed on the display area, an encapsulation layer disposed on the plurality of display elements, a bank layer disposed on the encapsulation layer, and including an opening overlapping the plurality of display elements, the opening extending in a direction, a lens disposed on the encapsulation layer and overlapping the opening, and a height control pattern layer disposed on the peripheral area and disposed between the lens and the encapsulation layer.

Other aspects, features, and advantages will be apparent from specific descriptions, claims, and drawings to carry out the disclosure below.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic perspective view of an electronic apparatus according to an embodiment;

FIG. 2 is a schematic plan view of a display apparatus according to an embodiment;

FIG. 3 is a schematic diagram of an equivalent circuit of a pixel circuit included in the display apparatus of FIG. 2;

FIG. 4 is a schematic enlarged plan view of a region A of the display apparatus 1 of FIG. 1;

FIG. 5 is a schematic cross-sectional view of the display apparatus of FIG. 4, taken along line B-B' of FIG. 4;

FIG. 6 is a schematic plan view of a display apparatus according to an embodiment;

FIG. 7 is a schematic cross-sectional view of the display apparatus of FIG. 6, taken along line C-C' of FIG. 6;

FIG. 8 is a schematic cross-sectional view of the display apparatus of FIG. 6, taken along line D-D' of FIG. 6;

FIGS. 9 to 13 are schematic cross-sectional views to explain a method of manufacturing a display apparatus, according to an embodiment;

FIG. 14 is a schematic plan view of a portion of a display apparatus being manufactured according to an embodiment; and

FIG. 15 is a schematic cross-sectional view to explain a method of manufacturing a display apparatus, according to a comparative example.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term "and/or" includes any and all combinations of one or more of the associated listed items. Throughout the disclosure, the expression "at least one of a, b, and c" indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below with reference to the drawings. However, the disclosure is not limited to embodiments described below and may be implemented in various forms.

While such terms as "first" and "second" may be used to describe various components, such components must not be limited to the above terms. The above terms are used to distinguish one component from another.

The singular forms "a," "an," and "the" as used herein are intended to include the plural forms as well unless the context clearly indicates otherwise.

It will be understood that the terms "comprise," "comprising," "include" and/or "including" as used herein specify the presence of stated features or components but do not preclude the addition of one or more other features or components.

In the description, "A and/or B" means A or B, or A and B. In the description, "at least one of A and B" means A or B, or A and B.

In the description, when various elements such as a layer, a region, a plate, and the like are disposed "on" another element, not only the elements may be disposed "directly on" the other element, but another element may be disposed therebetween.

It will be understood that when a layer, region, or component is referred to as being "connected" to another layer, region, or component, it may be "directly connected" to the other layer, region, or component or may be "indirectly connected" to the other layer, region, or component with other layer, region, or component interposed therebetween. For example, it will be understood that when a layer, region, or element is referred to as being "electrically connected" to another layer, region, or element, it may be "directly electrically connected" to the other layer, region, or element or may be "indirectly electrically connected" to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the case where a certain embodiment may be implemented differently, a specific process order may be performed in the order different from the described order. As an example, two processes successively described may be simultaneously performed substantially and performed in the opposite order.

In the description, when referring to a "plan view", it means an object portion is viewed from above. In the description, "on a plane" means "when viewed from a direction perpendicular to the substrate 100".

Hereinafter, embodiments will be described with reference to the accompanying drawings, wherein like reference numerals refer to like elements throughout and a repeated description thereof is omitted. Sizes of elements in the drawings may be exaggerated or reduced for convenience of explanation. As an example, the size and thickness of each element shown in the drawings are arbitrarily represented for convenience of description, and thus, embodiments are not necessarily limited thereto.

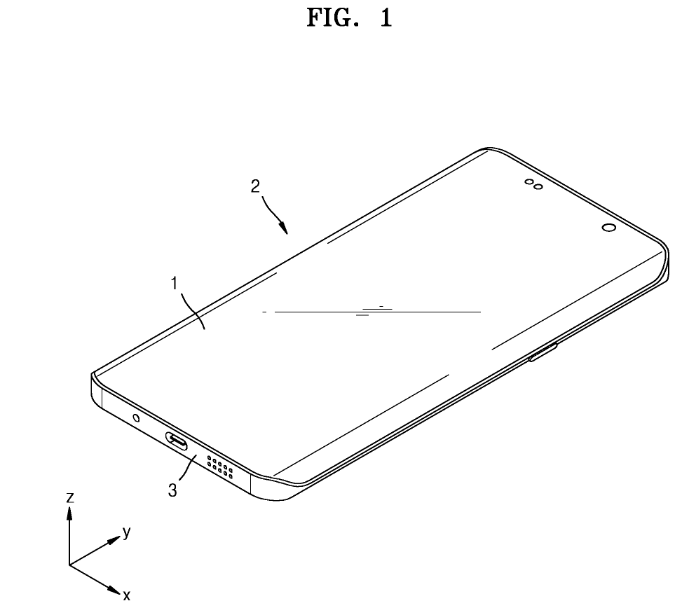

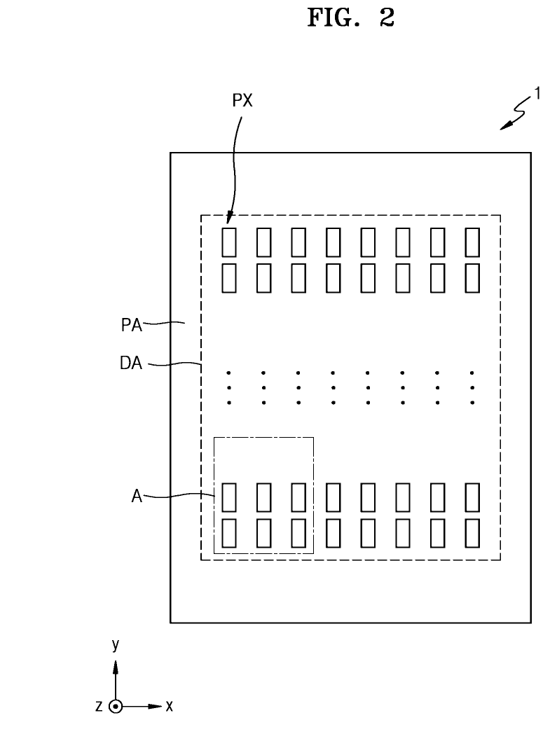

FIG. 1 is a schematic perspective view of an electronic apparatus 2 according to an embodiment. FIG. 2 is a schematic plan view of a display apparatus 1 according to an embodiment.

As shown in FIGS. 1 and 2, the display apparatus 1 may be an apparatus that displays moving images or still images. The display apparatus 1 may display a screen or to input or output data in the electronic apparatus 2.

Although it is shown in FIG. 1 that the display apparatus 1 is used in a mobile phone as an example, embodiments are not limited thereto. As an example, the display apparatus 1 may be used as a display screen in various electronic apparatuses including televisions, notebook computers, monitors, advertisement boards, Internet of things (IoT) apparatuses as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs).

For example, the display apparatus 1 according to an embodiment may be used in electronic apparatuses such as wearable devices including smartwatches, watchphones, glasses-type displays, and head-mounted displays (HMDs). In an embodiment, the display apparatus 1 may be applicable to a display screen in various electronic apparatuses. For example, the various electronic apparatuses may include instrument panels for automobiles, center fascias for automobiles, or center information displays (CIDs) arranged on a dashboard, room mirror display devices that replace side mirrors of automobiles, and display devices of an entertainment system arranged on the backside of front seats for backseat passengers in automobiles.

In an embodiment, the display apparatus 1 may be accommodated in a housing 3 of the electronic apparatus 2. The housing 3 may be a cover that protects internal elements such as the display apparatus 1 and form the exterior of the electronic apparatus 2. For example, the display apparatus 1 may be connected to an electronic module of the electronic apparatus 2 and driven on the electronic apparatus 2. Hereinafter, the display apparatus 1 is described.

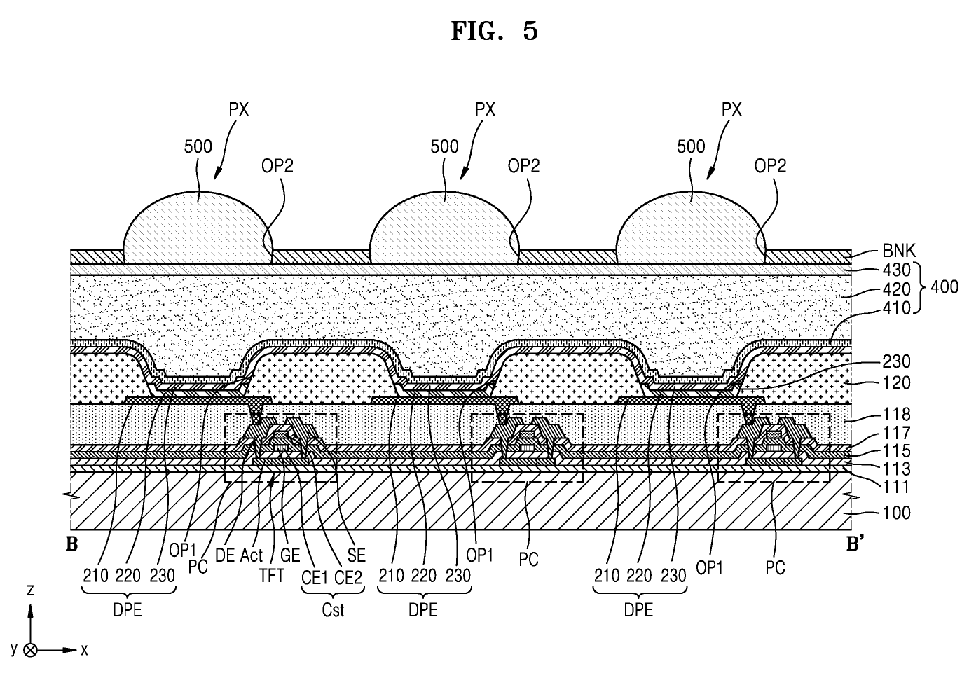

As shown in FIG. 2, the display apparatus 1 may include a display area DA and a peripheral area PA. For example, pixels PX may be disposed in the display area DA, and the peripheral area PA may be outside the display area DA. For example, the peripheral area PA may surround the display area DA entirely. This may be understood that a substrate 100 (see FIG. 5) included in the display apparatus 1 has the display area DA and the peripheral area PA.

Each pixel PX of the display apparatus 1 may be a region that emits light of a preset color. The display apparatus 1 may display images by using light from the pixels PX. As an example, each pixel PX may emit red, green, or blue light. As shown in FIG. 2, the display area DA may have a polygonal shape including a quadrangular shape. As an example, the display area DA may have a rectangular shape in which the horizontal length thereof is less than a vertical length thereof, a rectangular shape in which the horizontal length thereof is greater than the vertical length thereof, or a square shape. In another example, the display area DA may have various shapes such as an elliptical shape or a circular shape.

The peripheral area PA may be a non-display area in which the pixels PX are not disposed. A driver and the like for providing electrical signals or power to display elements respectively corresponding to the pixels PX may be disposed in the peripheral area PA. Pads may be disposed in the peripheral area PA. For example, electronic elements or a printed circuit board may be electrically connected to the pads. The pads may be disposed apart from each other in the peripheral area PA and electrically connected to a printed circuit board or an integrated circuit element.

Hereinafter, although an organic light-emitting display apparatus is described as an example of the display apparatus 1 according to an embodiment, embodiments are not limited thereto. In another embodiment, the display apparatus 1 according to an embodiment may be inorganic light-emitting display apparatus or a quantum-dot light-emitting display apparatus. As an example, an emission layer of a display element of the display apparatus 1 may include an organic material or an inorganic material. For example, the display apparatus 1 may include the emission layer and a quantum-dot layer disposed on a path of light emitted from the emission layer.

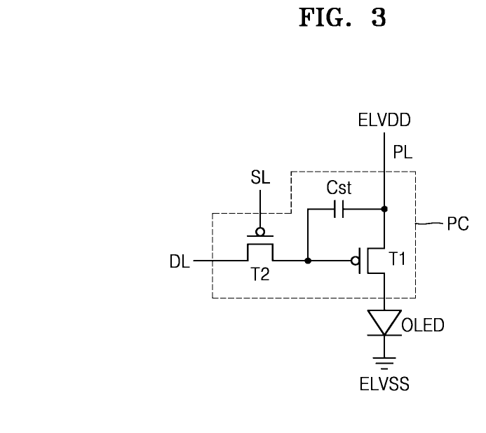

FIG. 3 is a schematic diagram of an equivalent circuit of a pixel circuit PC included in the display apparatus 1 of FIG. 2. The pixel circuit PC may be electrically connected to a display element, and one display element may correspond to one pixel PX. For example, the display element may emit red, green, or blue light. FIG. 3 shows an organic light-emitting diode OLED as the display element.

The pixel circuit PC may include a first transistor T1, a second transistor T2, and a storage capacitor Cst. The second transistor T2 may be a switching thin-film transistor, may be connected to a scan line SL and a data line DL and be turned on according to a switching signal, and transfer a data signal to the first transistor T1, the data signal being input from the data line DL, and the switching signal being input from the scan line SL. The storage capacitor Cst may include an end portion electrically connected to the second transistor T2, and the other end portion electrically connected to a driving voltage line PL. The storage capacitor Cst may store a voltage corresponding to a difference between a voltage transferred from the second transistor T2 and a driving power voltage ELVDD supplied to the driving voltage line PL.

The first transistor T1 may be a driving transistor, may be connected to the driving voltage line PL and the storage capacitor Cst, and control the magnitude of a driving current according to the voltage stored in the storage capacitor Cst, the driving current flowing from the driving voltage line PL to the organic light-emitting diode OLED. The organic light-emitting diode OLED may emit light having a preset brightness corresponding to the driving current. An opposite electrode of the organic light-emitting diode OLED may receive an electrode power voltage ELVSS.

Although it is described with reference to FIG. 3 that the pixel circuit PC includes two transistors and one storage capacitor, embodiments are not limited thereto. As an example, the number of transistors and the number of storage capacitors may be variously changed according to the design of the pixel circuit PC.

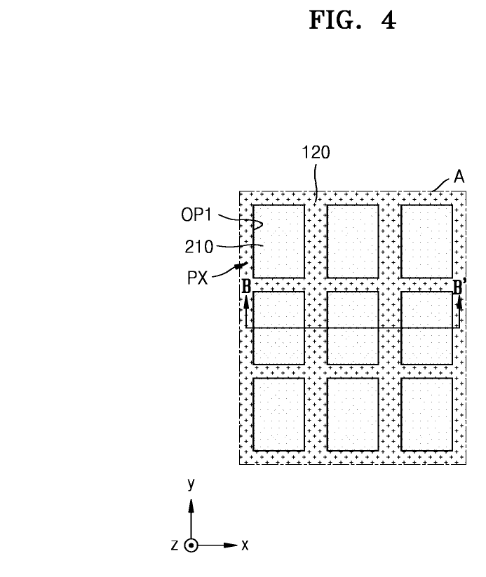

FIG. 4 is a schematic enlarged plan view of a region A of the display apparatus 1 of FIG. 1. For convenience, FIG. 4 shows a plan view of a pixel-defining layer 120.

As shown in FIG. 4, pixels PX may be disposed in the display area DA. Each pixel PX may emit, for example, red, green, or blue light. Red light may be light in a wavelength band of about 580 nm to about 780 nm, green light may be light in a wavelength band of about 495 nm to about 580 nm, and blue light may be light in a wavelength band of about 400 nm to about 495 nm.

A display element such as an organic light-emitting diode may correspond to each pixel PX. For example, each of the display elements included in the display apparatus 1 corresponds to each pixel PX of the display apparatus 1, and each of the display elements may emit red, green, or blue light. In the description, when one display element corresponds to one pixel, or one pixel corresponds to one display element, it means that one pixel is an emission area of one display element.

A stack structure of a pixel electrode, an emission layer, and an opposite electrode may form one display element, for example, an organic light-emitting diode. As an example, pixel electrodes 210 may be disposed on the display area DA of the substrate 100. The pixel electrodes 210 may be disposed apart from each other in a plan view. The pixel-defining layer 120 may be disposed on the pixel electrodes 210. The pixel-defining layer 120 may include pixel openings OP1. Each of the pixel openings OP1 may expose the central portion of a corresponding one of the pixel electrodes 210. For example, a portion of the pixel electrode 210 of the display element may be exposed through the pixel opening OP1. The pixel-defining layer 120 may not be disposed on a portion of the pixel electrode 210 exposed through the pixel opening OP1, but the pixel-defining layer 120 may be disposed on another portion of the pixel electrode 210 not exposed through the pixel opening OP1.

For example, emission layers that emit light may be respectively positioned in the pixel openings OP1 of the pixel-defining layer 120. The opposite electrode may be disposed on the emission layers. One pixel opening OP1 of the pixel-defining layer 120 may define the emission area of one display element. The emission area defined by the pixel opening OP1 may be defined as the pixel PX. Although it is shown in FIG. 4 that the pixel openings OP1 have the same size, embodiments are not limited thereto. The pixel openings OP1 may have different sizes.

FIG. 5 is a schematic cross-sectional view of the display apparatus 1 of FIG. 4, taken along line B-B' of FIG. 4. As shown in FIG. 5, the display apparatus 1 according to an embodiment includes the substrate 100.

The substrate 100 may include various flexible or bendable materials. As an example, the substrate 100 may include glass, metal, or polymer resin. For example, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide (SiO_{X}), silicon nitride (SiN_{X}), and/or silicon oxynitride (SiO_{X}N_{Y}), and the like) therebetween. However, various modifications may be made.

A display element DPE and a pixel circuit PC electrically connected to the display element DPE may be disposed on the substrate 100. For example, pixel circuits PC may be disposed on the substrate 100. Each of the pixel circuits PC may be electrically connected to a corresponding one of display elements DPE. Because the structures of the pixel circuits PC are equal to each other and the structures of the display elements DPE are equal to each other, one pixel circuit PC and one display element DPE are described.

The pixel circuit PC may be disposed on the substrate 100. The pixel circuit PC may include transistors TFT and a storage capacitor Cst. For convenience of illustration, one transistor TFT is shown in FIG. 5, and the transistor TFT may correspond to the first transistor T1 (see FIG. 3).

A buffer layer 111 including an inorganic material such as silicon oxide (SiO_{X}), silicon nitride (SiN_{X}), and/or silicon oxynitride (SiO_{X}N_{Y}) may be disposed between the transistor TFT and the substrate 100. The buffer layer 111 may increase flatness of the upper surface of the substrate 100, or prevent or reduce impurities from the substrate 100 and the like from penetrating a semiconductor layer Act of the transistor TFT.

As shown in FIG. 5, the transistor TFT may include the semiconductor layer Act including amorphous silicon, polycrystalline silicon, an organic semiconductor material, or an oxide semiconductor material. The transistor TFT may include a gate electrode GE, a source electrode SE, and/or a drain electrode DE. The gate electrode GE may include various conductive materials, have various layered structures, and include, for example, a Mo layer and an Al layer. In another example, the gate electrode GE may include a TiNₓ layer, an Al layer, and/or a Ti layer. The source electrode SE and the drain electrode DE may also include various conductive materials, have various layered structures, and include, for example, a Ti layer, an Al layer, and/or a Cu layer.

To ensure insulation between the semiconductor layer Act and the gate electrode GE, a gate insulating layer 113 may be disposed between the semiconductor layer Act and the gate electrode GE. For example, the gate insulating layer 113 may include an inorganic material such as silicon oxide (SiO_{X}), silicon nitride (SiN_{X}), and/or silicon oxynitride (SiO_{X}N_{Y}). Although it is shown in FIG. 5 that the gate insulating layer 113 has a shape corresponding to the entire surface of the substrate 100, and has a structure in which contact holes are formed in preset portions, embodiments are not limited thereto. As an example, the gate insulating layer 113 may be patterned in the same shape as the shape of the gate electrode GE.

For example, a first interlayer insulating layer 115 may be disposed on the gate electrode GE. For example, the first interlayer insulating layer 115 may include an inorganic insulating material such as silicon oxide (SiO_{X}), silicon nitride (SiN_{X}), and/or silicon oxynitride (SiO_{X}N_{Y}). The first interlayer insulating layer 115 may include a single layer structure or a multi-layered structure including the above materials. The insulating layer including the inorganic insulating material may be formed by chemical vapor deposition (CVD) or atomic layer deposition (ALD). This is also applicable to embodiments below and modifications thereof.

The storage capacitor Cst may include a first capacitor electrode CE1 and a second capacitor electrode CE2 overlapping each other with the first interlayer insulating layer 115 therebetween. The storage capacitor Cst may overlap the transistor TFT. With regard to this, although it is shown in FIG. 5 that the gate electrode GE of the transistor TFT functions as the first capacitor electrode CE1 of the storage capacitor Cst, embodiments are not limited thereto. As an example, the storage capacitor Cst may not overlap the transistor TFT. The second capacitor electrode CE2 of the storage capacitor Cst may include a conductive material including molybdenum (Mo), aluminum (Al), copper (Cu), or titanium (Ti) and have a single-layered structure or a multi-layered structure including the above materials.

A second interlayer insulating layer 117 may be disposed on the second capacitor electrode CE2 of the storage capacitor Cst. For example, the second interlayer insulating layer 117 may include an inorganic material such as silicon oxide (SiO_{X}), silicon nitride (SiN_{X}), and/or silicon oxynitride (SiO_{X}N_{Y}). The second interlayer insulating layer 117 may include a single layer structure or a multi-layered structure including the above materials.

The source electrode SE and the drain electrode DE may be disposed on the second interlayer insulating layer 117. The source electrode SE and the drain electrode DE may each include a material having high conductivity. The source electrode SE and the drain electrode DE may each include a conductive material including molybdenum (Mo), aluminum (Al), copper (Cu), or titanium (Ti) and include a single layer structure or a multi-layered structure including the above materials. As an example, the source electrode SE and the drain electrode DE may have a multi-layered structure of Ti/Al/Ti.

However, embodiments are not limited thereto. As an example, the transistor TFT may have only one of the source electrode SE and the drain electrode DE, or have neither of them. As an example, one transistor TFT may not have a drain electrode DE, another transistor TFT connected to the transistor TFT may not have a source electrode SE, and semiconductor layers Act of the two transistors may be connected to each other. This connection structure may result in a similar operational behavior to that which when a transistor TFT has a source electrode SE and another transistor TFT has a drain electrode DE, and the source electrode SE of the transistor TFT is connected to the drain electrode DE of the another transistor TFT.

As shown in FIG. 5, an organic insulating layer 118 may be disposed to cover the transistor TFT and the storage capacitor Cst. The organic insulating layer 118 may include an organic insulating material. As an example, the organic insulating layer 118 may include benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a mixture thereof. For example, a third interlayer insulating layer may be further disposed under the organic insulating layer 118. The third interlayer insulating layer may include an inorganic insulating material such as silicon oxide (SiO_{X}), silicon nitride (SiN_{X}), and/or silicon oxynitride (SiO_{X}N_{Y}).

The display element DPE may be disposed on the organic insulating layer 118. As an example, the display element DPE may be an organic light-emitting diode. The display element DPE may include the pixel electrode 210, an emission layer 220, and an opposite electrode 230. The opposite electrode 230 may be integrally provided over the entire surface of the display apparatus 1, and accordingly, commonly provided over the display elements DPE.

The pixel electrode 210 may include a light-transmissive conductive layer and a reflective layer. For example, the light-transmissive conductive layer may include a light-transmissive conductive oxide such as indium tin oxide (ITO), indium oxide (In₂O₃), or indium zinc oxide (IZO), and the reflective layer includes metal such as aluminum (Al) or silver (Ag). As an example, the pixel electrode 210 may have a three-layered structure of ITO/Ag/ITO. As shown in FIG. 5, the pixel electrode 210 may be electrically connected to the transistor TFT by being in contact with one of the source electrode SE and the drain electrode DE. For example, the pixel electrode 210 may be in contact with one of the source electrode SE and the drain electrode DE through a contact hole formed in the organic insulating layer 118.

The pixel-defining layer 120 may be disposed on the organic insulating layer 118. As described above, the pixel-defining layer 120 may include the pixel opening OP1. The pixel opening OP1 may expose the central portion of the pixel electrode 210 of the display element DPE. For example, the pixel-defining layer 120 may define the emission area of the display element DPE by including an opening corresponding to a pixel, e.g., an opening exposing at least the central portion of the pixel electrode 210. For example, in the case shown in FIG. 5, the pixel-defining layer 120 may increase a distance between the edge portion of the pixel electrode 210 and the opposite electrode 230 over the pixel electrode 210. Accordingly, arcs and the like may be prevented from occurring at the edge portions of the pixel electrode 210. The pixel-defining layer 120 may include an organic material such as polyimide or HMDSO.

The opposite electrode 230 may be disposed over the pixel electrode 210. The opposite electrode 230 may be integrally provided over the display elements DPE. Accordingly, the opposite electrode 230 may be disposed on the pixel electrodes 210. The opposite electrode 230 may include a light-transmissive conductive layer including ITO, In₂O₃, or IZO, and include a semi-transmissive layer including metal such as aluminum (Al) or silver (Ag). As an example, the opposite electrode 230 may be a semi-transmissive layer including magnesium (Mg) or silver (Ag).

The emission layer 220 that emits light may be disposed between the pixel electrode 210 and the opposite electrode 230. The emission layer 220 may emit red, green, or blue light. The emission layer 220 may include a polymer organic material or a low-molecular weight organic material that emits light having a preset color (e.g., red, green, or blue). As an example, the emission layer 220 may include a polymer material such as a polyphenylene vinylene (PPV)-based material and a polyfluorene-based material. The emission layer 220 may be formed by processes such as screen printing, inkjet printing, laser induced thermal imaging (LITI), or the like. However, embodiments are not limited thereto.

In an embodiment, a functional layer may be disposed under and on the emission layer 220. The functional layer may include a hole injection layer (HIL), a hole transport layer (HTL), an electron transport layer (ETL), and/or an electron injection layer (EIL). The functional layer may be integral over the pixel electrodes 210, or patterned to correspond to each of the pixel electrodes 210.

An encapsulation layer 400 may be disposed on the display element DPE. For example, the encapsulation layer 400 may be disposed on the opposite electrode 230. For example, because the display element DPE may be readily damaged by external moisture, oxygen, or the like, the encapsulation layer 400 may protect the display element DPE by covering the display element DPE. As shown in FIG. 5, the encapsulation layer 400 may include a first inorganic encapsulation layer 410, an organic encapsulation layer 420, and a second inorganic encapsulation layer 430. For example, the encapsulation layer 400 may be disposed on the opposite electrode 230. For example, the encapsulation layer 400 may include the first inorganic encapsulation layer 410, the second inorganic encapsulation layer 430, and the organic encapsulation layer 420 therebetween. The second inorganic encapsulation layer 430 may be disposed on the first inorganic encapsulation layer 410.

The first inorganic encapsulation layer 410 may cover the opposite electrode 230 and may include silicon oxide (SiO_{X}), silicon nitride (SiN_{X}), and/or silicon oxynitride (SiO_{X}N_{Y}). For example, other layers including a capping layer may be disposed between the first inorganic encapsulation layer 410 and the opposite electrode 230. Because the first inorganic encapsulation layer 410 is formed along a structure thereunder, the upper surface of the first inorganic encapsulation layer 410 may not be flat as shown in FIG. 5. The organic encapsulation layer 420 may cover the first inorganic encapsulation layer 410 and, unlike the first inorganic encapsulation layer 410, the upper surface of the organic encapsulation layer 420 may be substantially flat. The organic encapsulation layer 420 may include at least one material selected from among polyethylene terephthalate, polyethylene naphthalate, polycarbonate, polyimide, polyethylene sulfonate, polyoxymethylene, polyarylate, and hexamethyldisiloxane. The second inorganic encapsulation layer 430 may cover the organic encapsulation layer 420 and may include silicon oxide (SiO_{X}), silicon nitride (SiN_{X}), and/or silicon oxynitride (SiO_{X}N_{Y}).

Because the encapsulation layer 400 includes the first inorganic encapsulation layer 410, the organic encapsulation layer 420, and the second inorganic encapsulation layer 430, even when cracks occur inside the encapsulation layer 400, the cracks may not be connected between the first inorganic encapsulation layer 410 and the organic encapsulation layer 420 or between the organic encapsulation layer 420 and the second inorganic encapsulation layer 430 through the above multi-layered structure. With this configuration, forming of a path through which external moisture or oxygen penetrates the inside of the display apparatus 1 may be prevented or reduced.

A bank layer BNK may be disposed on the encapsulation layer 400. The bank layer BNK may include a bank opening OP2. The bank opening OP2 may overlap the display element DPE. For example, the bank opening OP2 may overlap the pixel opening OP1. The bank layer BNK may include a lyophobic material. Accordingly, because a lens-forming material coated on the bank layer BNK does not spread widely, the cross-section of a lens 500 formed on the bank layer BNK may have a shape similar to a semicircle. For this purpose, the bank layer BNK may include an organic material containing fluorine. In another example, the bank layer BNK may include at least one of benzocyclobutene (BCB), polyimide (PI), polyamide (PA), acrylic resin, and phenol resin. However, embodiments are not limited thereto. .

The lens 500 may be disposed on the encapsulation layer 400. The lens 500 may overlap the bank opening OP2. For example, the lens 500 may overlap the display element DPE and the pixel opening OP1. A portion of the lens 500 may be disposed in the bank opening OP2, and the other portion of the lens 500 may be disposed on the bank layer BNK. For example, a portion of the lens 500 may be positioned at the same distance as a distance between the bank layer BNK and the substrate 100, and another portion of the lens 500 may be positioned at a distance greater than a distance between the bank layer BNK and the substrate 100.

The lens 500 may adjust a path of light emitted from the emission layer 220 of the display element DPE and function as a condensing lens. The lens 500 may change a path of light travelling in a direction not parallel to an axis (z axis) perpendicular to the substrate 100 among light emitted from the emission layer 220 of the display element DPE, and allow the light to travel in a direction (+z direction) substantially perpendicular to the substrate 100.

For this purpose, the lens 500 may have a high refractive index. For example, the lens 500 may have a refractive index greater than a refractive index of a layer or atmosphere disposed on the lens 500. As an example, the refractive index of the lens 500 may be about 1.5 or more, for example, about 1.5 to about 1.8. As an example, the lens 500 may include an acryl-based organic material having a refractive index of about 1.6. In another example, the lens 500 may include an acryl-based organic material having a refractive index of about 1.65.

The lens 500 may include acrylic resin (e.g., polymethyl methacrylate, polyacrylic acid, and the like), ethylhexyl acrylate, pentafluoropropyl acrylate, polyethylene glycol dimethacrylate, poly(ethylene glycol) dimethacrylate or ethylene glycol dimethacrylate. The lens 500 may further include a heat curing agent and/or a photocuring agent, such as an epoxy.

In an embodiment, the lens 500 may be covered by a low-refractive layer having a refractive index less than the lens 500. As an example, the refractive index of the low refractive layer may be about 1.2 or more, for example, about 1.2 to about 1.5. The low-refractive layer may cover the upper entire surface of the substrate 100, and the upper surface of the low refractive layer may be substantially flat.

The low refractive layer may include acrylic resin (e.g., polymethyl methacrylate, polyacrylic acid, and the like), ethylhexyl acrylate, pentafluoropropyl acrylate, polyethylene glycol dimethacrylate, poly(ethylene glycol) dimethacrylate or ethylene glycol dimethacrylate. The refractive index of a material of the low refractive layer may be less than the refractive index of a material of the lens 500.

In an embodiment, the bank opening OP2 and the lens 500 may overlap the display elements DPE. For example, the bank opening OP2 and the lens 500 may overlap the pixel openings OP1.

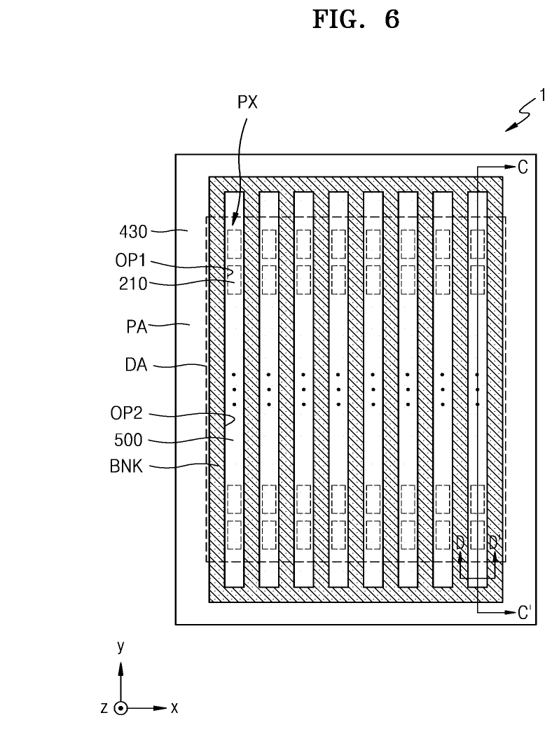

FIG. 6 is a schematic plan view of the display apparatus 1 according to an embodiment. FIG. 6 is a plan view on the second inorganic encapsulation layer 430 and shows the bank layer BNK and the lens 500. For convenience of description, FIG. 6 also shows the pixel opening OP1 disposed below the second inorganic encapsulation layer 430. For convenience of description, the display area DA and the peripheral area PA are shown in FIG. 6.

As shown in FIG. 6, the bank layer BNK may be disposed on the display area DA and the peripheral area PA. The lens 500 may be also disposed on the display area DA and the peripheral area PA.

For this purpose, the bank opening OP2 included in the bank layer BNK may extend in a direction. For example, each of bank openings OP2 may extend in a direction. For example, the bank opening OP2 may extend in a first direction (e.g., y axis direction) and extend from the display area DA to the peripheral area PA. As an example, the bank opening OP2 may extend from a portion of the peripheral area PA disposed adjacent to a side of the display area DA through the display area DA to a portion of the peripheral area PA disposed adjacent to an opposite side to the side.

For example, a single bank opening OP2 may overlap the pixel openings OP1. For example, the single bank opening OP2 may overlap the display elements DPE. For example, the pixel openings OP1 overlapping the single bank opening OP2 may be disposed in a direction. In another example, the display elements DPE overlapping the single bank opening OP2 may be disposed in a direction.

As described above, because the lens 500 overlaps the bank opening OP2, the lens 500 may also extend in a direction. For example, each of the lenses 500 may extend in a direction. For example, the lens 500 may extend in the first direction (e.g., y axis direction) and extend from the display area DA to the peripheral area PA. As an example, the lens 500 may extend from a portion of the peripheral area PA disposed adjacent to a side of the display area DA through the display area DA to a portion of the peripheral area PA disposed adjacent to an opposite side to the side.

For example, a lens (or single lens) 500 may overlap the pixel openings OP1. For example, the lens 500 may overlap the display elements DPE. For example, the pixel openings OP1 overlapping the lens 500 may be disposed in a direction. In another example, the display elements DPE overlapping the lens 500 may be disposed in a direction.

Accordingly, as shown in FIG. 6, when viewed from a direction perpendicular to the substrate 100, the bank layer BNK may surround the lens 500. For example, in a plan view, the bank layer BNK may surround the lens 500. In an embodiment, the display elements DPE overlapping the bank opening OP2 may emit light of the same color. As an example, display elements DPE overlapping one of the bank openings OP2 may emit red light. Display elements DPE overlapping another of the bank openings OP2 may emit green light, and display elements DPE overlapping another of the bank openings OP2 may emit blue light.

For example, the display elements DPE overlapping one lens 500 may emit light of the same color. As an example, display elements DPE overlapping one of the lenses 500 may emit red light. Display elements DPE overlapping another of the lenses 500 may emit green light, and display elements DPE overlapping another of the lenses 500 may emit blue light.

Although it is shown in FIG. 6 that the bank opening OP2 extends in the first direction (e.g., y axis direction), embodiments are not limited thereto. As an example, the bank opening OP2 may extend in a second direction (e.g., x axis direction) crossing the first direction (e.g., y axis direction). For example, the lens 500 may extend in the second direction (e.g., x axis direction).

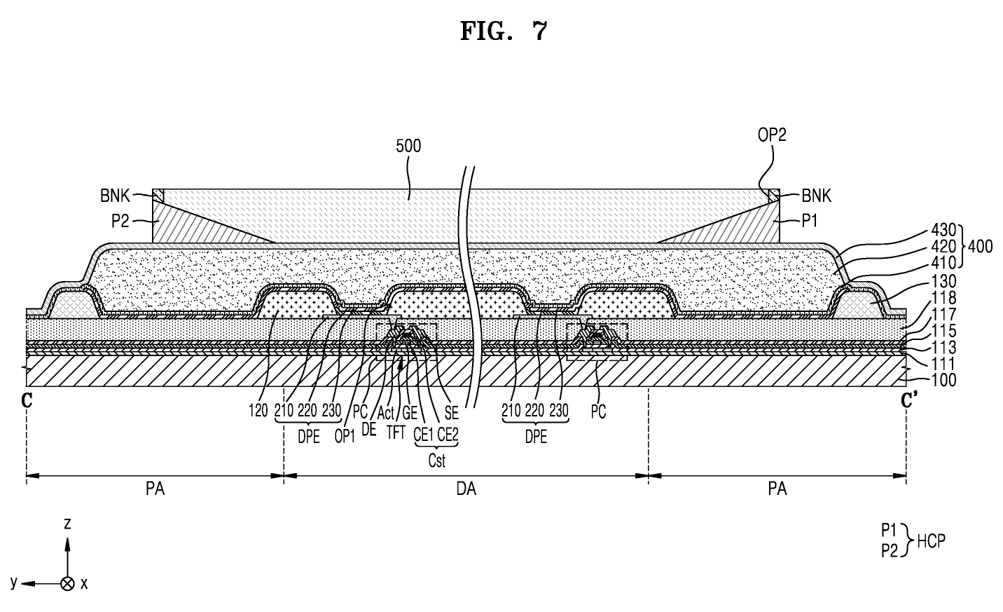

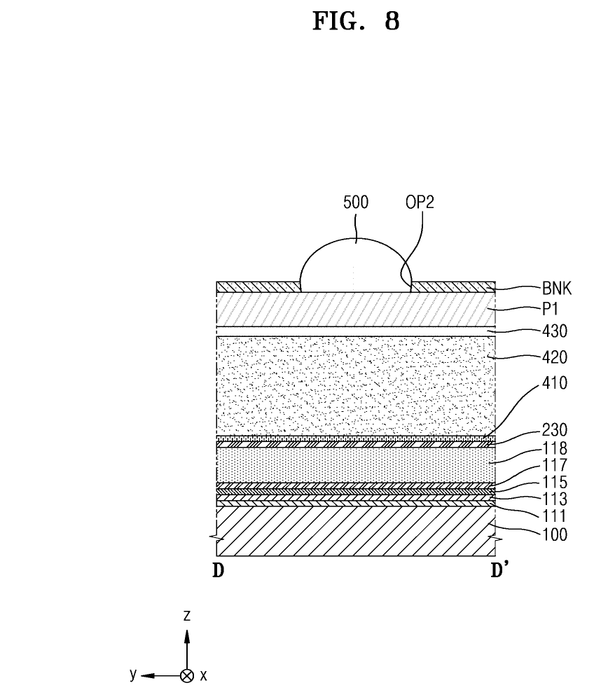

FIG. 7 is a schematic cross-sectional view of the display apparatus 1 of FIG. 6, taken along line C-C' of FIG. 6, and FIG. 8 is a schematic cross-sectional view of the display apparatus 1 of FIG. 6, taken along line D-D' of FIG. 6.

As shown in FIGS. 7 and 8, the display apparatus 1 may further include a height control pattern layer HCP disposed on the peripheral area PA. The height control pattern layer HCP may include a first pattern layer P1 and a second pattern layer P2. The first pattern layer P1 may be disposed adjacent to a side (or single side) of the display area DA, and the second pattern layer P2 may be disposed adjacent to the opposite side to the side of the display area DA with the display area DA therebetween. For example, the first pattern layer P1 may be disposed on a portion of the peripheral area PA adjacent to a side of the display area DA, and the second pattern layer P2 may be disposed on another portion of the peripheral area PA adjacent to the opposite side to the side of the display area DA.

As shown in FIGS. 7 and 8, the height control pattern layer HCP may be disposed between the lens 500 and the encapsulation layer 400. For example, a portion of the lens 500 may be disposed on the height control pattern layer HCP. In another example, the lens 500 may overlap a portion of the height control pattern layer HCP. As an example, a portion of the lens 500 may overlap a portion of the first pattern layer P1, and another portion of the lens 500 may overlap a portion of the second pattern layer P2.

For example, the lens 500 may overlap a portion of the height control pattern layer HCP in the peripheral area PA. For example, the lens 500 may overlap a portion of the first pattern layer P1 in a portion of the peripheral area PA adjacent to a side of the display area DA. The lens 500 may overlap a portion of the second pattern layer P2 in another portion of the peripheral area PA adjacent to the opposite side to the side of the display area DA.

As described above, in a plan view, because the bank layer BNK surrounds the lens 500, a portion of the bank layer BNK disposed on the peripheral area PA may be disposed on the height control pattern layer HCP. As an example, as shown in FIGS. 7 and 8, a portion of the bank layer BNK disposed on the peripheral area PA may be disposed on the first pattern layer P1, and another portion of the bank layer BNK disposed on the peripheral area PA may be disposed on the second pattern layer P2. For example, the end portion of the lens 500 may overlap the height control pattern layer HCP. The end portion of the lens 500 may be disposed on the height control pattern layer HCP.

For example, two opposite end portions of the lens 500 in a direction in which the lens 500 extends may overlap the height control pattern layer HCP. The two opposite end portions of the lens 500 in a direction in which the lens 500 extends may be disposed on the height control pattern layer HCP. For example, one of the two opposite end portions of the lens 500 in the direction in which the lens 500 extends may be disposed on the first pattern layer P1, and the other may be disposed on the second pattern layer P2.

In an embodiment, the thickness of the height control pattern layer HCP may increase as the height control pattern layer HCP moves away from the display area DA. For example, the thickness of the height control pattern layer HCP may be reduced toward the display area DA. As an example, as shown in FIG. 7, the thickness of the first pattern layer P1 may be reduced in a direction to the display area DA, and the thickness of the second pattern layer P2 may be reduced in the direction to the display area DA. In the description, the thickness of one layer or one pattern denotes the length of one layer or one pattern in a direction (e.g., z axis direction) perpendicular to the substrate 100.

In another embodiment, the height control pattern layer HCP may include a first portion adjacent to the display area DA and a second portion less adjacent to the display area DA than the first portion, and the thickness of the second portion may be greater than the thickness of the first portion. As an example, the first pattern layer P1 may include a first-1 portion adjacent to the display area DA and a first-2 portion less adjacent to the display area DA than the first-1 portion, and the thickness of the first-2 portion may be greater than the thickness of the first-1 portion. For example, the second pattern layer P2 may include a second-1 portion adjacent to the display area DA and a second-2 portion less adjacent to the display area DA than the second-1 portion, and the thickness of the second-2 portion may be greater than the thickness of the second-1 portion.

For example, the thickness of the height control pattern layer HCP may be different according to the position thereof, and the thickness of a portion of the thickest height control pattern layer HCP, for example, a portion of the height control pattern layer HCP farthest away from the display area DA may be about 8 µm. Unlike this, the bank layer BNK may have a uniform thickness over the display area DA and the peripheral area PA. For example, the thickness of the bank layer BNK disposed on the height control pattern layer HCP may be equal or similar to the thickness of the bank layer BNK disposed on the display area DA. Because the thickness of the bank layer BNK is sufficiently thin compared to the height control pattern layer HCP, even though a portion of the bank layer BNK is disposed on the height control pattern layer HCP, the thickness of the bank layer BNK may be equal or similar to the thickness of the bank layer BNK disposed on the display area DA. As an example, the thickness of the bank layer BNK may be about 2 µm.

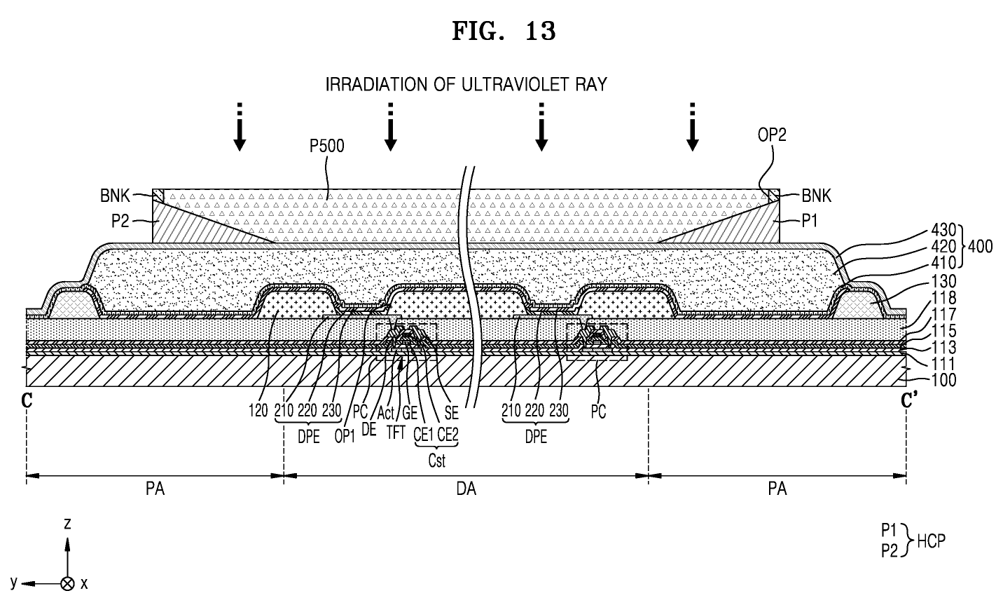

In the case where the two opposite end portions of the lens 500 in the direction in which the lens 500 extends are disposed on the height control pattern layer HCP, the height of a lens-forming material P500 (see FIG. 13) may be uniform during the process of manufacturing the display apparatus as described below. For example, a length from the upper surface of the encapsulation layer 400 to the upper surface of the lens-forming material P500 may not be reduced toward the end portion of the lens-forming material P500.

Accordingly, the height of the lens 500 may be uniform. A length from the upper surface of the encapsulation layer 400 to the upper surface of the lens 500 may not be reduced toward the end portion of the lens 500. In the description, the height of the lens-forming material P500 denotes a length from the upper surface of the encapsulation layer 400 to the upper surface of the lens-forming material P500 in a direction (e.g., z axis direction) perpendicular to the substrate 100. In the description, the height of the lens 500 denotes a length from the upper surface of the encapsulation layer 400 to the upper surface of the lens 500 in a direction (e.g., z axis direction) perpendicular to the substrate 100. Accordingly, in the display apparatus 1 according to the embodiment, light characteristics of the display elements DPE disposed adjacent to the peripheral area PA may not be deteriorated. For example, the display quality of the display apparatus 1 may be improved.

As shown in FIG. 7, a dam 130 may be disposed on the peripheral area PA of the substrate 100. For example, the dam 130 may be adjacent to the edge portion of the substrate 100 and be disposed on the peripheral area PA to surround the display area DA. The dam 130 may prevent or reduce a material for forming the organic encapsulation layer 420 from leaking to the outside of the dam 130 during a process of forming the organic encapsulation layer 420. The dam 130 and the pixel-defining layer 120 may include the same material. As an example, the dam 130 may be formed simultaneously with the pixel-defining layer 120 using the same material as a material of the pixel-defining layer 120. However, embodiments are not limited thereto, and the dam 130 may include a different material from a material of the pixel-defining layer 120 and be formed to a different height from a height of the pixel-defining layer 120. Although it is shown in FIG. 7 that there is one dam 130, embodiments are not limited thereto. As an example, the dam 130 may include sub-dams, and the number, the height, and the material of the sub-dams may be variously modified.

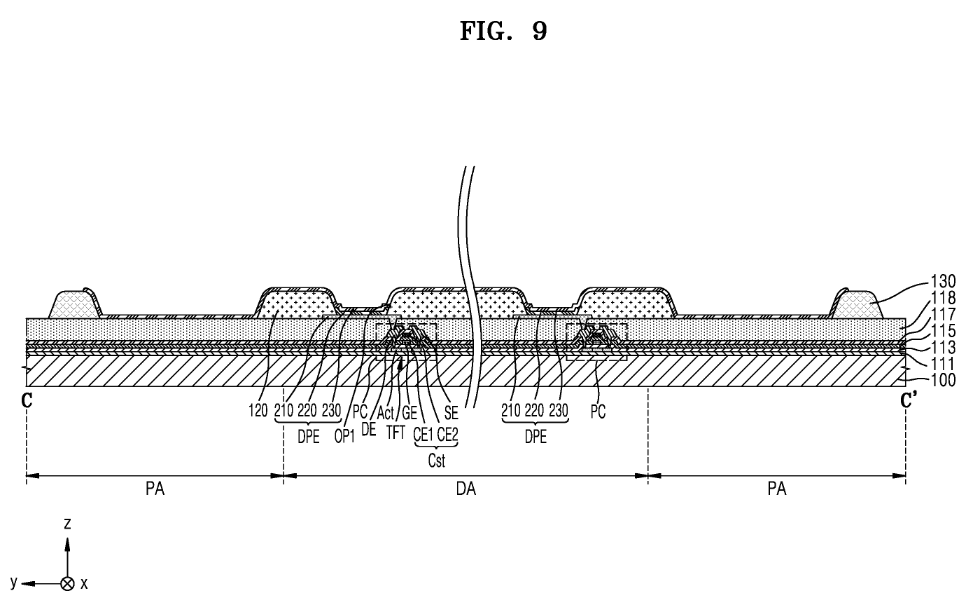

FIGS. 9 to 13 are schematic cross-sectional views to explain a method of manufacturing the display apparatus 1 according to an embodiment. For example, FIGS. 9 to 13 are schematic cross-sectional views showing a process of forming the lens 500 of the display apparatus 1. In FIGS. 9 to 13, for convenience of description, the method of manufacturing the display apparatus is described based on a cross-section of the display apparatus 1 of FIG. 6, taken along line C-C' of FIG. 6. Hereinafter, in describing the method of manufacturing the display apparatus according to an embodiment with reference to FIGS. 9 to 13, because the same reference numerals as those of FIGS. 1 to 8 denote the same members, repeated descriptions are omitted.

First, as shown in FIG. 9, the substrate 100 may be provided. The substrate 100 may include the display area DA and the peripheral area PA outside the display area DA. For example, in an operation of providing the substrate 100, the substrate 100 may be in a state in which the display element DPE and the pixel circuit PC electrically connected to the display element DPE are formed on the substrate 100. The display element DPE may be provided in plurality, and the pixel circuit PC may be provided in plurality. Each of the display elements DPE may be electrically connected to a corresponding one of the pixel circuits PC. For example, a region in which the display elements DPE are disposed may be the display area DA, and a region surrounding the display area DA may be the peripheral area PA of the substrate 100. For example, the substrate 100 including the display area DA on which the display elements DPE are disposed and the peripheral area PA outside the display area DA may be provided.

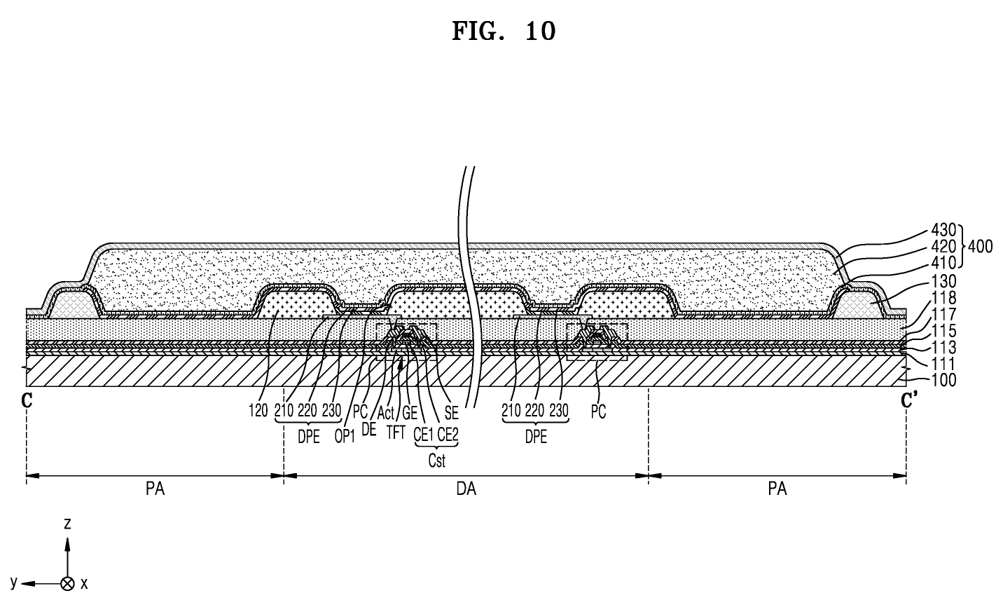

Subsequently, as shown in FIG. 10, the encapsulation layer 400 may be formed over the substrate 100. To prevent external moisture or oxygen from reaching the display elements DPE on the display area DA, the encapsulation layer 400 may be formed in the display area DA and at least a portion of the peripheral area PA. Accordingly, the encapsulation layer 400 may cover the display elements DPE. For example, the encapsulation layer 400 may be formed over the substrate 100 to cover the display elements DPE. The encapsulation layer 400 may include the first inorganic encapsulation layer 410, the second inorganic encapsulation layer 430, and the organic encapsulation layer 420 disposed between the first inorganic encapsulation layer 410 and the second inorganic encapsulation layer 430. For example, the first inorganic encapsulation layer 410, the organic encapsulation layer 420, and the second inorganic encapsulation layer 430 may be sequentially formed over the substrate 100.

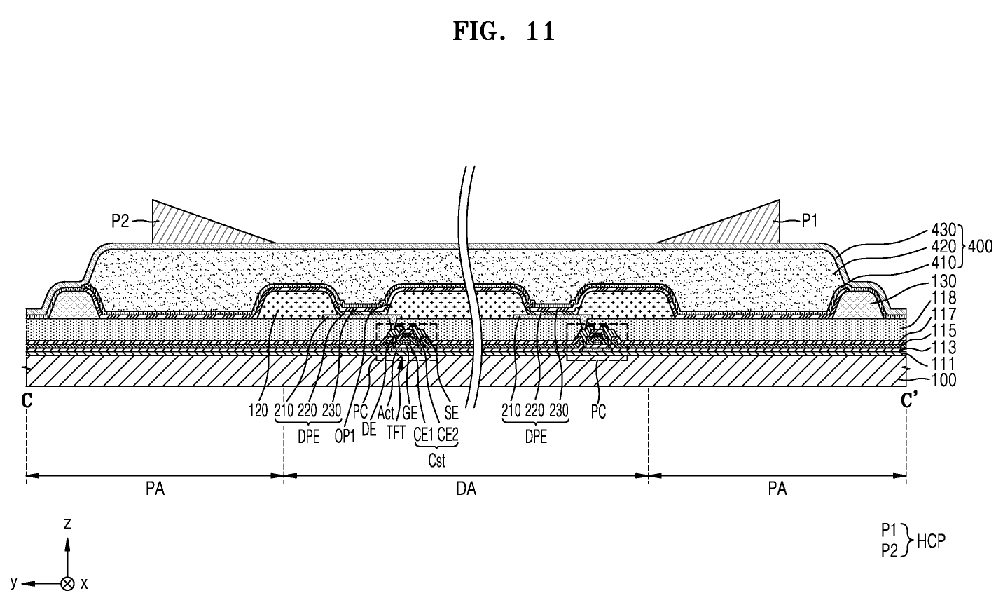

Subsequently, as shown in FIG. 11, the height control pattern layer HCP may be formed on the peripheral area PA. For example, the height control pattern layer HCP may include the first pattern layer P1 and the second pattern layer P2. The first pattern layer P1 may be formed in a portion of the peripheral area PA adjacent to a side of the display area DA, and the second pattern layer P2 may be formed in a portion of the peripheral area PA adjacent to the opposite side to the side of the display area DA with the display area DA therebetween. For example, the height control pattern layer HCP may be formed to include the first pattern layer P1 disposed adjacent to a side of the display area DA and the second pattern layer P2 disposed adjacent to the opposite side to the side of the display area DA with the display area DA therebetween.

The height control pattern layer HCP may be formed such that the thickness of the height control pattern layer HCP may increase as the height control pattern layer HCP moves away from the display area DA. For example, the height control pattern layer HCP may be formed such that the thickness of the height control pattern layer HCP may decrease toward the display area DA. As an example, the first pattern layer P1 may be formed such that the thickness of the first pattern layer P1 may decrease toward the display area DA, and the second pattern layer P2 may be formed such that the thickness of the second pattern layer P2 may decrease toward the display area DA.

In another embodiment, the height control pattern layer HCP may include the first portion adjacent to the display area DA and the second portion less adjacent to the display area DA than the first portion, and the height control pattern layer HCP may be formed such that the thickness of the second portion may be greater than the thickness of the first portion. As an example, the first pattern layer P1 may include the first-1 portion adjacent to the display area DA and the first-2 portion less adjacent to the display area DA than the first-1 portion, and the first pattern layer P1 may be formed such that the thickness of the first-2 portion may be greater than the thickness of the first-1 portion. For example, the second pattern layer P2 may include the second-1 portion adjacent to the display area DA and the second-2 portion less adjacent to the display area DA than the second-1 portion, and the second pattern layer P2 may be formed such that the thickness of the second-2 portion may be greater than the thickness of the second-1 portion.

In forming the height control pattern layer HCP having different thicknesses according to the position, a photolithography process that uses a half-tone mask and an etching process may be used. In the photolithography process, a negative photoresist or a positive photoresist may be used. However, embodiments are not limited thereto, and as long as it is a process generally used to form one layer or one pattern having different thicknesses according to the position, any process may be used.

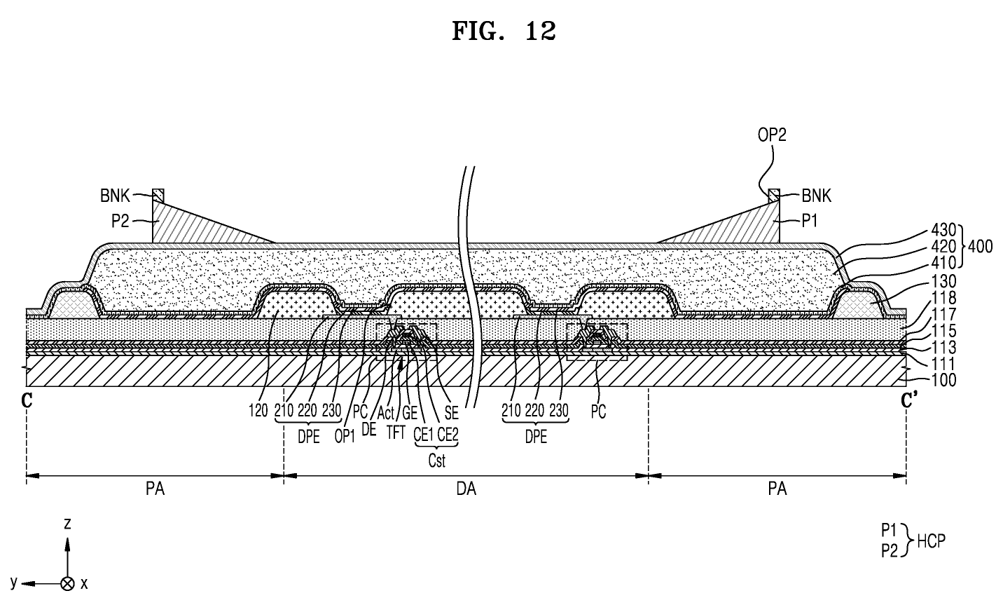

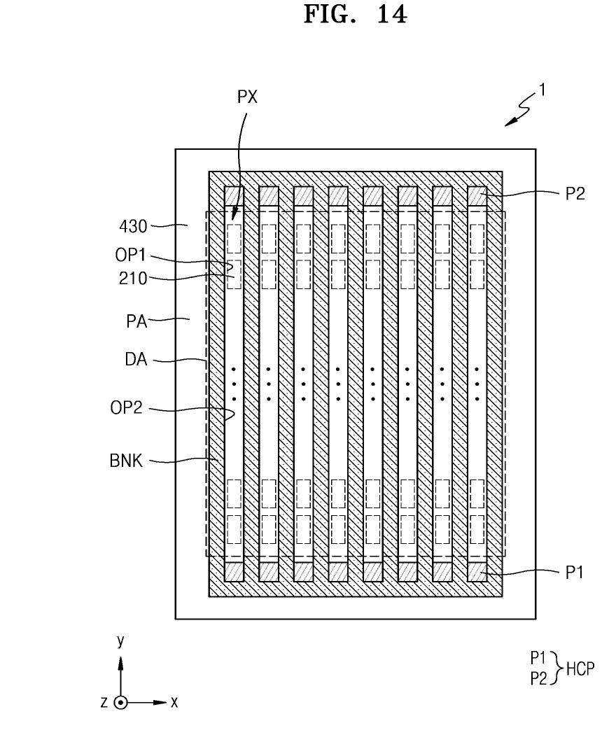

Subsequently, as shown in FIG. 12, the bank layer BNK may be formed on the encapsulation layer 400. The bank layer BNK may be formed in the display area DA and the peripheral area PA. The bank layer BNK may include the bank opening OP2 overlapping the display elements DPE and extending in a direction. For example, as shown in FIG. 14, which is a schematic plan view of a portion of the display apparatus being manufactured according to an embodiment, each of the bank openings OP2 of the bank layer BNK may extend in a direction. For example, a single bank opening OP2 may overlap the pixel openings OP1. For example, the single bank opening OP2 may overlap the display elements DPE. For convenience, FIG. 14 shows a plan view on the second inorganic encapsulation layer 430. For convenience of description, the pixel opening OP1 disposed below the second inorganic encapsulation layer 430 is shown together. For convenience of description, the display area DA and the peripheral area PA are shown in FIG. 14.

The bank opening OP2 may extend from the display area DA to the peripheral area PA. For example, the bank opening OP2 may extend from a portion of the peripheral area PA disposed adjacent to a side of the display area DA through the display area DA to a portion of the peripheral area PA disposed adjacent to an opposite side to the side. Accordingly, a portion of the bank layer BNK formed in the peripheral area PA may be formed on the height control pattern layer HCP. For example, a portion of the bank opening OP2 may overlap a portion of the height control pattern layer HCP.

Subsequently, as shown in FIG. 13, the lens 500 may be formed on the encapsulation layer 400. For example, the lens-forming material P500 may be coated to fill the bank opening OP2, and an ultraviolet ray may be irradiated to the lens-forming material P500. Accordingly, as shown in FIG. 6, the lens 500 overlapping the bank opening OP2 may be formed.

As an example, the lens-forming material P500 may be discharged on the encapsulation layer 400 through an inkjet printing process. The coated lens-forming material P500 may fill the bank opening OP2. For example, the lens-forming material P500 may be coated on the encapsulation layer 400 to fill the bank opening OP2.

The lens-forming material P500 may be a solution manufactured by mixing an acryl-based polymer and/or an acryl-based monomer with an organic solvent. For example, the lens-forming material P500 may be a solution manufactured by mixing an organic material that forms the lens 500 with an organic solvent through photocuring and the like. The acryl-based polymer may include polymethyl methacrylate, polyacrylic acid, or polyethylene glycol dimethacrylate, and the acryl-based monomer may include ethylhexyl acrylate, pentafluoropropyl acrylate, or ethylene glycol dimethacrylate. However, embodiments are not limited thereto.

The organic solvent may be any solvent that is used to dissolve acryl-based polymers and acryl-based monomers. However, embodiments are not limited thereto. As an example, the organic solvent may include at least one of propylene glycol methyl ether acetate (PGMEA), ethyl lactate, 2-methoxyethyl acetate, propylene glycol monomethyl ether, methyl ethyl ketone, methyl isobutyl ketone, and 1-methyl-2-pyrrolidinone.

The lens-forming material P500 may further include a photocuring agent. The photocuring agent may be any photocuring agent that is used to photo-cure acryl-based polymers and acryl-based monomers. However, embodiments are not limited thereto. For example, the lens-forming material P500 may be a solution in which an acryl-based polymer and/or an acryl-based monomer and a photocuring agent are dissolved in an organic solvent.

An ultraviolet ray may be irradiated to the coated lens-forming material P500. Accordingly, the coated lens-forming material P500 may be photocured to form the lens 500. For example, the lens 500 may be a photocured coated lens-forming material P500. For example, an ultraviolet ray having a light amount of about 1,000 mJ/cm² to about 3,000 mJ/cm² may be irradiated to the coated lens-forming material P500. As an example, an ultraviolet ray having a light amount of about 2,000 mJ/cm² may be irradiated to the coated lens-forming material P500. An ultraviolet ray having a wavelength of about 300 nm to about 400 nm may be used for photocuring. A light emitting diode (LED) or metal halide may be used as the ultraviolet source. For example, the lens 500 may be formed by irradiating an ultraviolet ray to the coated lens-forming material P500.

Because the bank opening OP2 extends from the display area DA to the peripheral area PA, the lens-forming material P500 may be coated over the display area DA and the peripheral area PA. Accordingly, the lens-forming material P500 may be coated on a portion of the height control pattern layer HCP. For example, the lens-forming material P500 may be coated on a portion of the first pattern layer P1 and a portion of the second pattern layer P2. Accordingly, as shown in FIG. 6, the two opposite end portions of the lens 500 in the direction in which the lens 500 extends may be disposed on the height control pattern layer HCP.

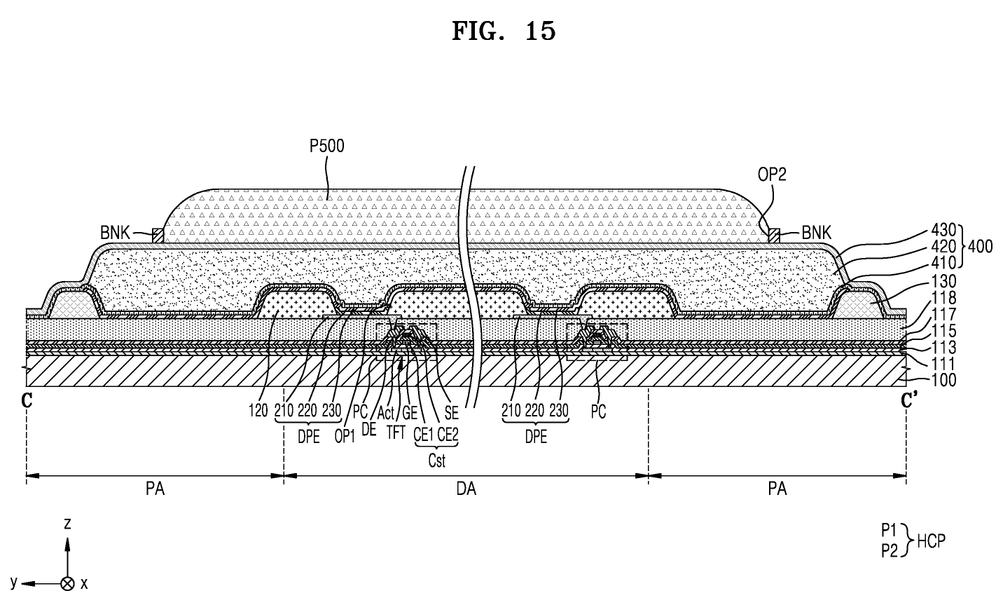

Generally, in case of coating the lens-forming material P500 and filling the bank opening OP2 to form the lens 500, the height of the lens-forming material P500 filling the bank opening OP2 may decrease toward the end portion of the lens-forming material P500. Accordingly, as shown in FIG. 15, which is a schematic cross-sectional view to explain a method of manufacturing a display apparatus according to a comparative example, the height of a portion of the lens-forming material P500 disposed on the peripheral area PA may be different from the height of a portion of the lens-forming material P500 disposed on the display area DA. For example, a length from the upper surface of the encapsulation layer 400 to the upper surface of the lens-forming material P500 may be reduced toward the end portion of the lens-forming material P500.

FIG. 15 shows a case of coating the lens-forming material P500 on the encapsulation layer 400 where the height control pattern layer HCP is not present to fill the bank opening OP2. For example, a length from the upper surface of the encapsulation layer 400 to the upper surface of the lens-forming material P500 in the peripheral area PA may be less than a length from the upper surface of the encapsulation layer 400 to the upper surface of the lens-forming material P500 in the display area DA.

Even in the case of the lens 500 formed by the lens-forming material P500, a length from the upper surface of the encapsulation layer 400 to the upper surface of the lens 500 may decrease toward the end portion of the lens 500. For example, a length from the upper surface of the encapsulation layer 400 to the upper surface of the lens 500 in the peripheral area PA may be less than a length from the upper surface of the encapsulation layer 400 to the upper surface of the lens 500 in the display area DA. Accordingly, in case of using the lens 500 as a condensing lens, light characteristics of the display elements DPE disposed adjacent to the peripheral area PA may be deteriorated.

According to the embodiment, the lens-forming material P500 filling the bank opening OP2 may be coated on a portion of the height control pattern layer HCP. Accordingly, a length from the upper surface of the encapsulation layer 400 to the upper surface of the lens-forming material P500 may not be reduced toward the end portion of the lens-forming material P500. For example, a length from the upper surface of the encapsulation layer 400 to the upper surface of the lens-forming material P500 in the peripheral area PA may be equal or similar to a length from the upper surface of the encapsulation layer 400 to the upper surface of the lens-forming material P500 in the display area DA.

Likewise, a length from the upper surface of the encapsulation layer 400 to the upper surface of the lens 500 may not be reduced toward the end portion of the lens 500. For example, a length from the upper surface of the encapsulation layer 400 to the upper surface of the lens 500 in the peripheral area PA may be equal or similar to a length from the upper surface of the encapsulation layer 400 to the upper surface of the lens 500 in the display area DA. For example, the lens 500 may have a uniform height. Accordingly, in the display apparatus 1 manufactured according to the embodiment, light characteristics of the display elements DPE disposed adjacent to the peripheral area PA may not be deteriorated. For example, the display quality of the display apparatus 1 may be improved.

According to an embodiment, because the lens has a uniform height, the display apparatus with improved display quality, the method of manufacturing the display apparatus, and the electronic apparatus may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate including a display area and a peripheral area outside the display area;
a plurality of display elements disposed on the display area;
an encapsulation layer disposed on the plurality of display elements;
a bank layer disposed on the encapsulation layer, and including an opening overlapping the plurality of display elements, the opening extending in a direction;
a lens disposed on the encapsulation layer and overlapping the opening of the bank layer; and
a height control pattern layer disposed on the peripheral area and disposed between the lens and the encapsulation layer.

2. The display apparatus of claim 1, wherein the lens extends from the display area to the peripheral area.

3. The display apparatus of claim 2, wherein the lens extends from a portion of the peripheral area disposed adjacent to a side of the display area through the display area to a portion of the peripheral area disposed adjacent to an opposite side to the side.

4. The display apparatus of claim 1, wherein, in a plan view, the bank layer surrounds the lens.

5. The display apparatus of claim 1, wherein
the bank layer is disposed on the display area and the peripheral area, and
a portion of the bank layer disposed on the peripheral area is disposed on the height control pattern layer.

6. The display apparatus of claim 5, wherein an end portion of the lens is disposed on the height control pattern layer.

7. The display apparatus of claim 1, wherein a thickness of the height control pattern layer is reduced as being closer to the display area.

8. The display apparatus of claim 1, wherein the height control pattern layer includes:
a first pattern layer disposed adjacent to a side of the display area, and
a second pattern layer disposed adjacent to an opposite side to the side with the display area.

9. The display apparatus of claim 8, wherein
a portion of the lens overlaps a portion of the first pattern layer, and
another portion of the lens overlaps a portion of the second pattern layer.

10. The display apparatus of claim 1, wherein the encapsulation layer includes:
a first inorganic encapsulation layer,
a second inorganic encapsulation layer, and
an organic encapsulation layer disposed between the first inorganic encapsulation layer and the second inorganic encapsulation layer.

11. A method of manufacturing a display apparatus, the method comprising:
providing a substrate including a display area on which a plurality of display elements are disposed, and a peripheral area outside the display area;
forming an encapsulation layer on the substrate to cover the plurality of display elements;
forming a height control pattern layer on the peripheral area;
forming, on the encapsulation layer, a bank layer including an opening overlapping the plurality of display elements, the opening extending in a direction; and
forming, on the encapsulation layer, a lens overlapping the opening of the bank layer.

12. The method of claim 11, wherein the forming of the lens includes: coating a lens-forming material on the encapsulation layer to fill the opening; and
irradiating an ultraviolet ray to the lens-forming material.

13. The method of claim 12, wherein the forming of the lens includes coating the lens-forming material over the display area and the peripheral area.

14. The method of claim 12, wherein the forming of the bank layer includes forming the bank layer such that the opening extends from a portion of the peripheral area disposed adjacent to a side of the display area through the display area to a portion of the peripheral area disposed adjacent to an opposite side to the side.

15. The method of claim 12, wherein the forming of the bank layer includes forming the bank layer on the display area and the peripheral area and forming the bank layer such that a portion of the bank layer formed on the peripheral area is formed on the height control pattern layer.

16. The method of claim 15, wherein the forming of the lens includes coating the lens-forming material on a portion of the height control pattern layer.

17. The method of claim 12, wherein the forming of the height control pattern layer includes forming the height control pattern layer such that a thickness of the height control pattern layer is reduced as being closer to the display area.

18. The method of claim 12, wherein the forming of the height control pattern layer includes:
forming a first pattern layer on a portion of the peripheral area disposed adjacent to a side of the display area; and
forming a second pattern layer on another portion of the peripheral area disposed adjacent to an opposite side to the side.

19. The method of claim 18, wherein the forming of the lens includes coating the lens-forming material on a portion of the first pattern layer and a portion of the second pattern layer.

20. An electronic apparatus comprising:
a display apparatus; and
a housing accommodating the display apparatus and forming an exterior of the electronic apparatus,
wherein the display apparatus includes:
a substrate including a display area and a peripheral area outside the display area;
a plurality of display elements disposed on the display area;
an encapsulation layer disposed on the plurality of display elements;
a bank layer disposed on the encapsulation layer, and including an opening overlapping the plurality of display elements, the opening extending in a direction;
a lens disposed on the encapsulation layer and overlapping the opening; and
a height control pattern layer disposed on the peripheral area and disposed between the lens and the encapsulation layer.
